(19) United States
(12) Patent Application Publication
(10) Pub. No.: US 2015/0014299 A1
(43) Pub. Date: Jan. 15, 2015

(54) PROXIMITY SENSOR AND OPERATOR CONTROL PANEL FORMED THEREWITH

(71) Applicant: ZF Friedrichshafen AG, Friefrichshafen (DE)

(72) Inventors: Markus Toesko, Auerbach (DE); Alexander Graf, Friedrichshafen (DE)

(21) Appl. No.: 14/385,078

(22) PCT Filed: Feb. 1, 2013
(86) PCT No.: PCT/EP2013/051991

§ 371 Date: Sep. 12, 2014

(30) Foreign Application Priority Data
Mar. 14, 2014 (DE) 10 2012 203 954.6

(51) Int. Cl. H05B 1/02; G01R 21/00; G01B 7/00

(52) U.S. Cl. CPC H05B 1/0202; G01B 7/003; G01R 21/00; H05B 1/0258
USPC 219/490; 324/71.1

(57) ABSTRACT

A proximity sensor, in particular for use with a control panel, preferably a stove top, wherein the proximity sensor has at least one antenna, one frequency generator, and one power detector, wherein the at least one antenna is coupled to the frequency generator in order to supply it with power, wherein the power detector is supplied for determining a power level at the at least one antenna, which varies in relation to the radiated power, and wherein the power detector is further provided for emitting a signal relating to the determined power level.

The present invention relates to a proximity sensor according to the preamble of Claim 1. Moreover, the invention relates to a control panel formed with the proximity sensor according to the preamble of Claim 8, in particular for a stove top.

Different sensor assemblies for use with control panels, in particular in stove tops, are known in the prior art. An inductive proximity sensor technology is known, for example, from DE 10 2010 007 620 A1, which makes use of transmitter and receiver coils with a phase shift determined thereon, a sensor technology is known from DE 20 2006 003 115 U1, which functions in a capacitive manner, and its activation results from pressure applied to the control panel, and a sensor technology is known from DE 10 2006 052 875, which is formed by infrared sensor elements.

These known sensor assemblies pose problems with use in stove tops, however. An inductive sensor technology can be affected in an unintentional manner by metal structures, e.g. by the metal housing of a stove top, the capacitive sensor technology, among others, can be affected by water or steam on the stove top, and the infrared sensors can be affected, e.g. by the glass surface of a stove top, in particular by varying coloring.

Based on this, the present invention addresses the object of providing a sensor and a control panel formed therewith, which overcomes these disadvantages, and in particular, can be implemented in a cost-effective manner.

This objective is attained according to the invention by the features of Claim 1 and Claim 8. Advantageous embodiments and developments are the subject matter of the dependent claims.

In accordance with the invention, a proximity sensor is proposed, in particular for use with a control panel, preferably an electric device, furthermore, in particular, a stove top. Advantageously, a contact-free triggering of a switching procedure is enabled by means of the proximity sensor, wherein the proximity sensor can, moreover, advantageously be operated without moving parts, i.e. is free of wear in this respect.

The proximity sensor according to the invention has at least one antenna, one frequency generator, and one power detector. As such, the at least one antenna is coupled to the frequency generator in order to supply it with power, in particular via a supply point, preferably at the base of the antenna. An incident wave can, starting from the frequency generator, can be conducted to the antenna via a line and preferably a coupling element.

It is preferably provided that the frequency generator continuously excites the antenna, or provides it with power, during the operation of the proximity sensor, or, for example, when numerous antennas are used, it is further preferred that the respective antennas are powered, or excited, respectively, in particular in intervals, at a discreet frequency, in particular, all antennas are powered or excited at a single, discreet frequency. A frequency of this type corresponds, in particular, to the operational frequency of the proximity sensor. A respective antenna is powered, furthermore, in particular, with, or by, a continuous power, or output power, respectively, from the frequency generator.

Preferably the respective antenna has a narrow bandwidth for the discreet frequency, or operational frequency, respectively, of the proximity sensor, and a high performance level as well.

It is also provided in the scope of the present invention, in particular, that the respective antennas are adjusted to the frequency generator in terms of impedance, wherein the antennas are preferably excited by the frequency generator with a small amount of energy. In this manner, an advantageously low power consumption is obtained during operation of the sensor.

The frequency generator, which is comprised of components preferably also functioning in the same manner with regard to their terminology, can be advantageously created as an integrated component, i.e. as a chip, in particular in the form of a frequency synthesizer. An antenna, preferably according to electrical principles, can be formed in a cost-effective and simple manner, as a planar, in particular, printed or stamped, antenna, preferably on a carrier substrate of the proximity sensor, which, for example, is provided in the form of a printed circuit board. Otherwise, as a matter of course, other embodiments of the antenna are conceivable, in particular different geometries as well. If necessary, a shield may be provided between the antennas and/or sensors.

With the proximity sensor according to the invention, which is subject, in particular, to the electromagnetic operating principle, the power detector is capable of determining a power supplied to the at least one antenna, or, respectively, it determines a power, supplied to the at least one antenna, which varies, depending on the power emitted. For this, the power detector can be coupled in a suitable manner to the antenna, or, respectively, it can be electrically connected thereto.

Preferably, the power detector is coupled to the antenna by means of a coupling device, or a coupling element, respectively, e.g. via a directional coupler or a splitter. The power detector can, advantageously, precisely determine a power, which varies depending on the emitted power, by means of a coupling element of this type, which is preferably designed for disconnecting, or decoupling, respectively, a returning wave component from incident wave components. This is because the determination can occur based on the returning wave, and the determination is not complicated by an overlapping with the incident wave. Preferably the frequency generator can also be coupled to the antenna by means of the coupling element.

The power detector, primarily comprised of components having the same functions regarding their terminology, can likewise be created in a cost-effective manner as an integrated component, wherein it is preferably provided that the frequency generator, the at least one antenna, and the power detector are accommodated on a shared carrier substrate in the form, in particular, of a single printed circuit board, preferably also including a respective coupling element. In this manner, an extremely small proximity sensor can be obtained.

The power detector is furthermore capable, depending on the determined power, which depends, in particular, on an emitted power, of emitting a signal, or, respectively, it outputs a signal. A switching procedure can be triggered by means of the emitted signal, in particular by means of threshold comparison, wherein the threshold values can define switching points.

It is preferred thereby that the proximity sensor furthermore comprises an evaluation device, in particular a microcontroller, coupled to the power detector, in particular, directly connected electrically therewith, and to which the signal from the power detector can be supplied. By way of example, the evaluation device can define, or implement, the threshold values, which, when reached, enable a triggering of a respective switching procedure by means of the evaluation device. A switching procedure can be caused in a simple manner by means of a correlation of the signals emitted by the power detector with at least one of the defined switching thresholds.

Preferably the evaluation device can be designed, alternatively, or in addition thereto, for correlating signal patterns or characteristics with one another, in particular for a correlation of the power detector signal with at least one stored signal pattern. In this regard, predetermined signal characteristics, such as the signal duration, a signal deviation, in particular over time, the shape of the signal, or further signal characteristics, for example, which define an intended proximity profile for the proximity sensor, or its switching actuation, respectively, can be correlated with the power detector signal. In this manner, a switching procedure can be triggered, accordingly, depending on whether the intended proximity profile is recognized in the course of the correlation.

With one embodiment of the invention, it is provided that the proximity sensor is designed having a plurality of antennas. A proximity sensor of this type preferably has a multiplexer, which is designed, for example, as an IC, and by means of which a respective antenna can be selectively coupled to the frequency generator, or by means of which the power at an antenna can be selectively determined, respectively.

As a result, it is advantageously possible to activate or prompt, respectively, numerous antennas by means of a single frequency generator, and/or also by means of a single power detector. In this case, the antennas are supplied with power in intervals, or their power is prompted at intervals, depending on the power emitted, i.e. for the duration of the respective interconnection with the multiplexer. For each interval, and each antenna, a signal can be emitted by means of the power detector, and if necessary, a switching signal can be generated by the evaluation unit. The multiplexer can preferably be controlled by the evaluation unit, i.e. via a signal connection.

Preferably, the multiplexer and/or the evaluation unit can likewise be formed on a carrier substrate for the proximity sensor, in particular on a carrier substrate preferably in the form of a printed circuit board, on which the one or more antennas for the proximity sensor are also disposed, for example, in turn as an IC. It can further be provided, preferably, that the frequency generator and the power detector, as well as, in particular, the evaluation unit and/or the multiplexer, are formed as a single-piece IC, or chip.

In order to be able to function as a proximity sensor, it is provided—as noted above—that the antennas are each excited with a low energy at a discreet frequency. In particular due to the adjustment of the antennas, the main portion of the power is radiated in this case, such that power detector coupled to the antenna, in particular via a coupling element, as described above, only measures a small amount of power. An element placed in the electromagnetic field of the antenna, i.e. an interacting element, such as a finger on the hand of a user, affects the tuning of the antenna thereby, e.g. by lowering the resonance frequency. As a result, the wave generated by the frequency generator is largely reflected, in particular at the base of the respective antenna, and cannot be radiated. Due to this increased power, a signal is provided at the power detector in the form of a first sensor output signal, which represents this increased power. This emitted signal can, for example, be a voltage signal. This signal can be evaluated by an evaluation unit of the sensor, as explained above, e.g. by means of threshold or pattern comparison, as an actuation signal, or as a switching signal, respectively, in the form of a second output signal.

A proximity sensor designed in the manner described above can, advantageously, be produced in a simple and cost-effective manner, wherein further advantages—as could be determined in the scope of the present invention, in particular in the course of attempts in this regard—particularly in use with a stove top, are obtained. On one hand, the proximity sensor is hardly affected in a noticeable manner by metallic structures in a stove top, such as metallic frames, for example. The glass surfaces and the glass colors of a stove top plate no longer play a role, wherein—if, accordingly, the sensor is affected—this can be compensated for by the geometry of the antenna, which can be readily adapted for this purpose.

The removal of a stove top plate, or glass plate, respectively, from the sensor can also be compensated for by the geometry of the antenna. In his case, the glass plate can lie directly on the proximity sensor, or its antenna(s), or be spaced apart therefrom, as well. The tolerances typical for the installation do not substantially affect the function of the proximity sensor thereby. A thin water layer, such as condensation, for example, lying above the sensor, has an advantageously small effect on the proximity sensor in comparison with that found in the prior art.

Furthermore, by means of the proposed proximity sensor it is also possible to reliably distinguish, advantageously, between a desired forms of actuation and interferences originating from HF applications, e.g. microwaves, W-LAN. This is because a provided proximity profile, in particular a finger, corresponds to a signal with a continuous signal increase, or a clear characteristic, which can be distinguished with respect to the shape of the signal and its duration, advantageously, from interference signals. With respect to the generated signal, the signals from a microwave, for example, are short. An undesired actuation, not corresponding to the provided proximity profile, e.g. by means of bodies of a different type than that of a finger, for example, can be avoided by means of an evaluation, or comparison, respectively, of the signal pattern generated by means of the at least one proximity sensor in the case of a proximity thereto.

In the scope of the present invention, a control panel having at least one proximity sensor, as described above, is proposed, wherein at least one interaction position, at which a user can preferably interact with the at least one proximity sensor, or the control panel, respectively, is defined for the control panel. This is provided, in particular, for the manual interaction thereby, i.e. by means of the hand of a user, in particular by means of a finger thereof. The interaction can occur thereby, preferably, without contact.

The control panel can have a surface for visualizing interaction positions, e.g. on a substrate, on which the intended interaction positions are marked, or illustrated, such that they can be recognized by the user, wherein the surface can be disposed adjacent to the proximity sensor, in particular on a side of the substrate located opposite the surface.

With the control panel according to the invention, it is provided that the at least one interaction position, in particular all of the interaction positions, are allocated one antenna of the, or a, proximity sensor, by means of which the control panel generates a signal relating to a power determined for the same, in particular a switching signal. The switching signal can be generated by an evaluation device, which can preferably be a component of a control unit for the control panel.

The control panel is preferably the control panel for a stove top. For this, the substrate can, in particular, be a glass plate, which forms the stove top. The control panel, in particular for a stove top, can preferably be designed, in particular by means of at least one evaluation device, to then generate, by means of a respective proximity sensor, a switching signal, if a signal emitted by the power detector corresponds to a stored characteristic, i.e. a predefined proximity profile, preferably that of a finger. This enables a stove top to be able to prevent an undesired actuation, by means of, for example, a pot or a hand, i.e. due to the different signal characteristics, or proximity profiles, respectively.

Thus, a reliably functioning and advantageously inexpensively producible stove top can be created using the present invention.

Further features and advantages of the invention can be derived from the following description of embodiment examples of the invention, based on the figures in the drawings, which illustrate details substantial to the invention, and from the claims. The individual features can each be realized individually, or collectively, in arbitrary combinations, in a variation of the invention.

Preferred embodiments of the invention shall be explained below based on the attached drawings. Shown are:

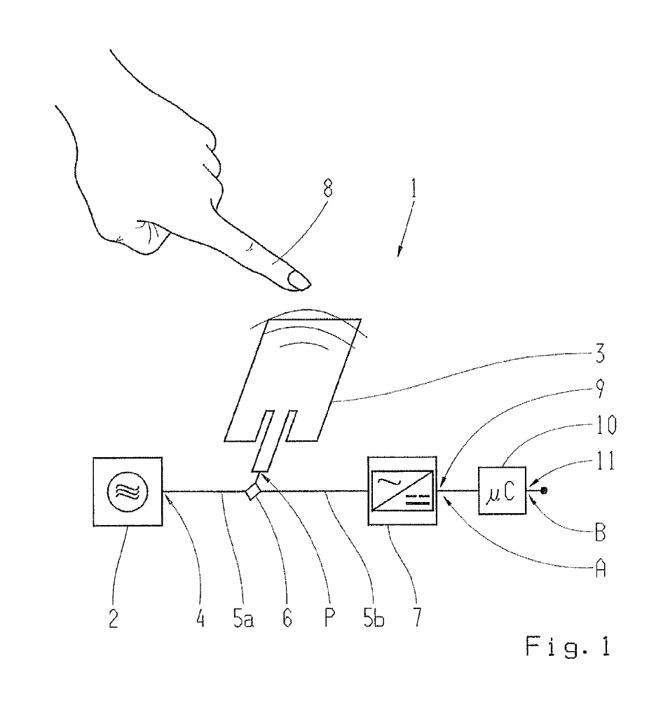

FIG. 1 by way of example, and schematically, a proximity sensor having an evaluation device according to one possible embodiment of the invention;

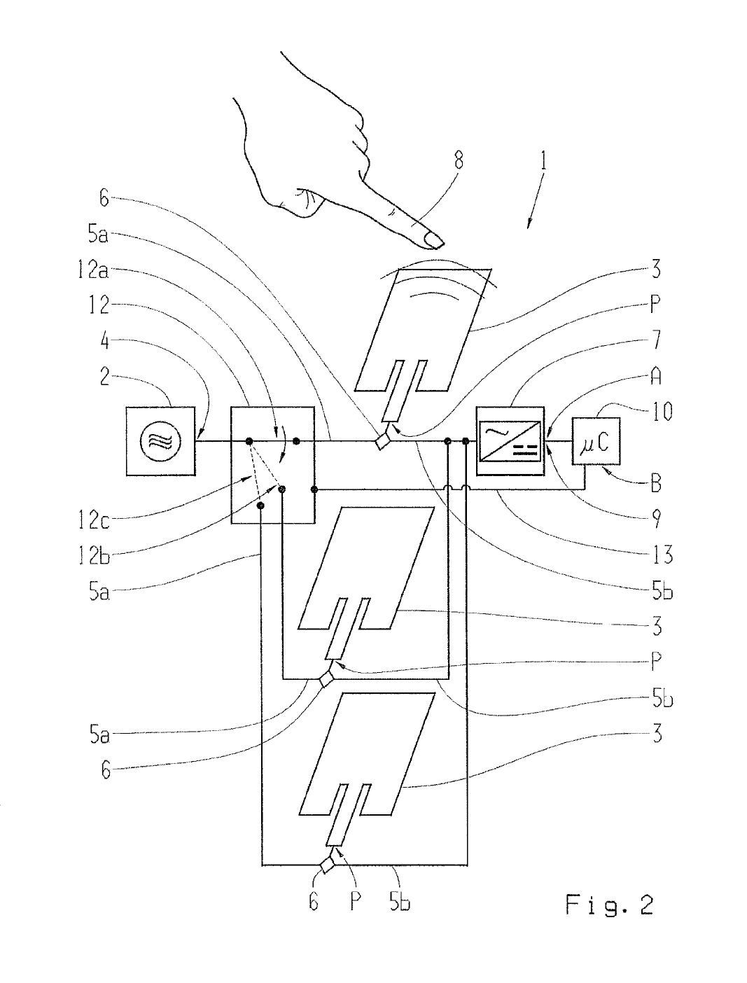

FIG. 2 by way of example, and schematically, a proximity sensor having numerous antennas, and a multiplexer, according to another possible embodiment of the invention;

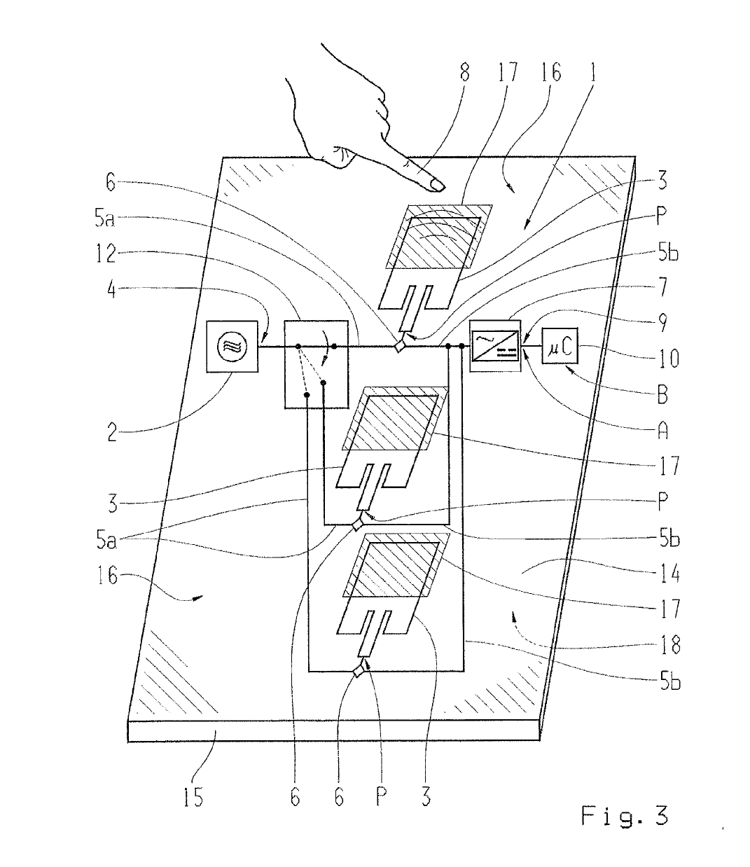

FIG. 3 by way of example, and schematically, a control panel according to one possible embodiment of the invention.

In the following description of the figures, identical elements, or functions, respectively, are provided with identical reference symbols.

FIG. 1 shows a proximity sensor 1 having a frequency generator 2 in the form of a frequency synthesizer-component. A planar antenna 3 is coupled to the frequency generator 2, for which this antenna is connected to the output 4 of the frequency generator by means of a power supply 5a, a directional coupler 6, and in particular, its base P.

The frequency generator 2 excites the antenna 3 at a fixed operational frequency, with only one current, in particular a constant current, or power, wherein the antenna 3 has a high performance level and a small bandwidth at the operational frequency. The antenna 3 is a printed planar antenna 3 in the present case, i.e. on a carrier substrate, not shown, which can be manufactured inexpensively in a simple manner.

Furthermore, a power detector 7 is connected to the antenna 3—by means of the coupling element 6 and a line 5b—which determines a power level at the antenna 3, i.e. at its base P. The power determined by means of the power detector 7 coupled to the antenna 3 varies thereby, dependent on the power radiated by the antenna 3, wherein the power detector 7 draws on the returning wave, which is decoupled by means of the directional coupler 6.

As illustrated in FIG. 1, the radiated power can, in particular, vary, and thus, in this connection, the power determined at the antenna 3 can vary, if an interaction element 8 enters the electromagnetic field of the antenna 3, particular its proximal field, when the proximity to the proximity sensor 1 is to be detected for the output of a corresponding signal. The interaction element 7 can, as shown, be a finger 8 of a user, or alternatively, another body.

When the interaction element 8 is brought within the field of the antenna, in particular its proximal field, the antenna is brought out of tune, based on a capacitive coupling, for example, by means of which power is reflected at the base 6 of the antenna 3, and not radiated. This increased, or varied, power, i.e. the returning wave, is determined by the power detector 7. As a result, that a signal A corresponding to the increased power is provided at an output 9 of the power detector 7 by the same, an analog voltage signal, for example, is generated. This can represent a first output signal of the proximity sensor 1.

An evaluation device 10 for the proximity sensor 1 in the form of a microcontroller is connected, or coupled, to the output 9, which correlates the signal at the output 9 with internal threshold waves, or alternatively, or in addition thereto, with a stored signal pattern, which corresponds to a predefined proximity profile, in order to generate, or provide, a switching signal B, depending on the correlation, or comparison, results thereof. This can be available as a further, or alternative, individual output signal of the proximity sensor 1 at an output 11, i.e. of the evaluation device 10. Alternatively, or in addition, the switching signal B can be further processed internally by means of the evaluation device 10, which, for example, can be a component of a control unit.

FIG. 2 shows, in an exemplary manner, an embodiment of a proximity sensor 1, with which the proximity sensor 1, in each case, has numerous antennas 3. With the embodiment according to FIG. 2, this is supplied with energy by means of a multiplexer 12, i.e. selectively.

As can be seen in FIG. 2, the multiplexer 12 is coupled, or connected, to the output 4 of the frequency generator 2. An antenna 3 can be coupled to the output 4 of the frequency generator 2 in each switching setting 12a, 12b, 12c of the multiplexer 12, in each case, and thus can be selectively excited by the frequency generator. The multiplexer 12 can be controlled thereby via the evaluation device 10, which preferably functions as a de-multiplexer, i.e. via the control line 13.

In order to prompt the antennas 3, in each case in intervals, the multiplexer 13 can be reversed in its various switching settings via the control line 13, i.e. for one interval in each case, within which interval, the respective antenna 3 is thus supplied with power. For this interval, the power detector 7, which advantageously can be coupled to all of the antennas 3 via a single input in connection with the line segments 5b, i.e. in each case via a directional coupler 6, determines a power supplied to the antenna 3, and emits a sensor signal A based thereon, preferably to the evaluation device, in order to subsequently be able to generate a switching signal B.

For this, all of the antennas 3 can be successively excited in intervals in a continuous sequence, wherein the lengths of the intervals are selected, preferably temporally, such that a proximity of an interaction element 8 to a respective antenna 3 can be reliably detected.

FIG. 3 shows, by way of example, a control panel 14, which is formed by means of a proximity sensor 1. The control panel 14 has a substrate 15, which provides a surface 16 on which interaction positions 17 are marked. The interaction positions 17 each define positions at which an interaction with a user, in particular via an interaction element 8, preferably a finger, should take place.

For this, each interaction position 17 is allocated one antenna 3, which is disposed such that a proximity to an interaction element 8 at the interaction position 3 can cause a de-tuning of the antenna 3, i.e. a change to the power that can be detected by means of the power detector 7. Thus, for each antenna 3, a signal A can be generated that relates to the determined power, in this case in intervals, alternatively, e.g. continuously, e.g. through the use of numerous sensors 1. This is supplied, in each case, to the evaluation device 10 for the control panel 14, which generates a switching signal B, dependent on the signal A.

The configuration of the proximity sensor 1 is obtained thereby on the side 18 of the substrate 15 opposite the surface 16, in particular, adjacent thereto, e.g. at a spacing therefrom, or abutting it. It is also conceivable to form an antenna 3 thereby, or at least part of the proximity sensor 1, directly on the substrate 15.

In order to create the control panel 14, it is also conceivable to provide numerous sensors 1, which are formed, e.g. by means of at least one antenna 3. The output signals A, or B, respectively, thereof can be transmitted to a superordinated evaluation unit for the control panel.

A stove top, in general, e.g. an electric appliance, can be advantageously formed with the control panel 14, or a proximity sensor 1, wherein the substrate 15 in the case of a stove top is preferably a stove top plate, in particular, a glass plate. The evaluation device 10 can be a component of a stove top control unit thereby, wherein, depending on the switching signal B, burners on the stove top can be turned on or off, for example, or turned up or down, for example. A stove top can, advantageously, easily be made capable of distinguishing between the proximity of an intended interaction element, in particular a finger, or a different element, by means of the proximity sensor 1. For this, a signal correlation functionality, as described above, can be implemented in the proximity sensor, or a stove top control unit formed therewith, in particular in the evaluation device. For this, a stored signal, or proximity profile, respectively, can be correlated with any actual proximity, such that a safety function can be implemented in a simple manner. In other applications of the invention, the substrate can be a ceramic or plastic material, for example.

### REFERENCE SYMBOLS

1 proximity sensor
2 frequency generator
3 antenna
4 output 2
5a power supply line
5b line
6 coupling element
7 power detector
8 interaction element
9 output 7
10 evaluation device
11 output 10
12 multiplexer
13 control line
14 control panel
15 substrate
16 surface 15
17 interaction position
18 side 15 opposite 16
A first output signal
B second output signal
P base

1. A proximity sensor for use with a control panel, the proximity sensor comprising:
an antenna;
a frequency generator; and
a power detector, wherein the antenna is coupled to the frequency generator and configured to supply power to the frequency generator, wherein the power detector is configured to determine a radiated power level at the antenna, and wherein the power detector is further configured to emit a signal indicative of the radiated power level.

2. The proximity sensor according to claim 1 the proximity sensor further comprising an evaluation device coupled to the power detector.

3. The proximity sensor according to claim 2, wherein the evaluation device is configured to generate a switching signal in response to determining that the signal correlates to a stored signal characteristic.

4. The proximity sensor according to claim 1, wherein the antenna comprises a plurality of antennas, and the proximity sensor further comprises a multiplexer configured to selectively couple one of the plurality of antennas to the frequency generator such that the power detector is capable of determining the radiated power level of the selectively coupled one of the plurality of antennas.

5. The proximity sensor according to claim 1, wherein the antenna comprises a planar antenna, and wherein the proximity sensor further comprises a coupling element between the antenna and the frequency generator.

6. The proximity sensor according to claim 1, wherein the frequency generator, the antenna, and the power detector, are provided on a carrier substrate.

7. The proximity sensor according to claim 1, wherein the frequency generator is configured to supply power to the antenna at a discreet frequency.

8. A control panel for providing interaction between a stovetop and a user, the control panel comprising:
a proximity sensor comprising:
an antenna;
a frequency generator; and
a power detector, wherein the antenna is coupled to the frequency generator and configured to supply power to the frequency generator, wherein the power detector is configured to determine a radiated power level at the antenna, and wherein the power detector is configured to emit a signal indicative of the radiated power level,
and wherein the radiated power level is indicative of an interaction position of the user relative to the antenna.

9. The control panel according to claim 8, wherein the control panel comprises a plurality of proximity sensors wherein each one of the plurality of proximity sensors is configured to determine one of a plurality of interaction positions of the user relative to the antenna of each one of the plurality of proximity sensors.

10. The control panel according claim 8, wherein the control panel comprises a substrate, wherein the interaction position is defined above a surface of the substrate, and wherein the antenna is disposed adjacent to, on the side of, opposite to, or on the surface of the substrate.

11. The control panel according to claims 8, wherein the control panel is configured to generate a switching signal from the proximity sensor if the signal corresponds to a stored characteristic.

12. A stove top comprising a proximity sensor, the proximity sensor comprising:
an antenna;
a frequency generator; and
a power detector, wherein the antenna is coupled to the frequency generator and configured to supply power to the frequency generator, wherein the power detector is configured to determine a radiated power level at the antenna, and wherein the power detector is further configured to emit a signal indicative of the radiated power level.

13. The proximity sensor of claim 2, wherein the evaluation device is a microprocessor.

14. The proximity sensor of claim 2, wherein the stored signal characteristic is a signal duration, a signal deviation, a signal voltage, or a signal shape.

15. The control panel of claim 8, wherein the interaction position comprises a position at which the proximity sensor is configured to generate a switching signal.

16. The control panel of claim 8, wherein the interaction position comprises a position at which the user contacts the antenna.

17. The proximity sensor of claim 6, wherein the proximity sensor is formed in a single unit.

18. The proximity sensor of claim 1, wherein the antenna is a printed antenna.
